(19) United States
(12) Patent Application Publication
(10) Pub. No.: US 2021/0202441 A1
(43) Pub. Date: Jul. 1, 2021

(54) SYSTEM AND METHOD FOR STACKING WIRE-BOND CONVERTED FLIP-CHIP DIE

(71) Applicant: INTEL CORPORATION, SANTA CLARA, CA (US)

(72) Inventors: ENG HUAT GOH, Ayer Itam (MY); CHU AUN LIM, Hillsboro, OR (US); UPENDRA R. SHETH, Phoenex, AZ (US); ROBERT STARKSTON, Phoenix, AZ (US)

(73) Assignee: INTEL CORPORATION, SANTA CLARA, CA (US)

(21) Appl. No.: 16/070,510

(22) PCT Filed: Feb. 5, 2016
(86) PCT No.: PCT/US2016/016881

§ 371 Date: Jul. 16, 2018

(51) Int. Cl. H01L 25/065; H01L 23/00

(52) U.S. Cl. CPC H01L 25/0657; H01L 2224/73203; H01L 24/17; H01L 24/16; H01L 25/0652; H01L 24/73; H01L 24/11; H01L 24/83; H01L 2924/1436; H01L 2224/16225; H01L 2224/1703; H01L 2224/81203; H01L 2224/73253; H01L 2924/30107; H01L 2225/06517; H01L 24/81

(57) ABSTRACT

Various embodiments are generally directed to an electronic assembly comprising at least two dies stacked on top of each other. Metal columns of different heights electrically connect the dies to a system substrate.

### BACKGROUND

Analog and/or digital circuits may be created on substrates made of silicon or other materials; these substrates may be placed in a package for durability, reliability, or other similar reasons. In order to communicate with other circuits and/or systems, the package may include one or more conductors that electrically connect an input and/or output signal in the circuit within the package to the package exterior to thereby permit the other circuits and/or systems to send and receive electrical signals to the circuit within the package. The package may further include conductors that supply power to the circuit within the package or any other type of conductor.

### BRIEF DESCRIPTION OF THE DRAWINGS

FIGS. 1A, 1B, and 1C illustrate top and bottom views of example embodiments of an electronic assembly that includes stacked dies;

FIG. 2 illustrates a cross-sectional view of an example embodiment of an electronic assembly that includes stacked dies;

FIG. 3 illustrates a bottom view of an example embodiment of an electronic assembly that includes stacked dies;

FIG. 4 illustrates a cross-sectional view of an example embodiment of an electronic assembly that includes stacked dies;

FIGS. 5A, 5B, and 5C illustrate top and corresponding cross-sectional views of an example embodiment of an electronic assembly that includes stacked dies;

FIG. 6 illustrates a cross-sectional view of an example embodiment of an electronic assembly that includes stacked dies;

FIGS. 7A, 7B, 7C, 7D, and 7E illustrate an exemplary method of manufacturing an electronic assembly that includes stacked dies; and

FIG. 8 illustrates an exemplary flow of manufacturing an electronic assembly that includes stacked dies.

### DETAILED DESCRIPTION

Conductors in a package may be wire-bond conductors in which a metal pad on the substrate is wire-bonded to a pin on the package, allowing other circuits and/or systems to send and/or receive signals to any circuit disposed on the substrate connected to the metal pad. Wire-bond conductors may be simple and/or cheap to produce and manufacture, but they have disadvantages including parasitic inductance that may limit the signal frequency and/or edge rate they can support. The conductors may instead be bumps on the substrate that, when the substrate is flipped over, connect directly to another substrate or other circuit or system. Large numbers of these “flip-chip” substrates may, however, consume an unacceptably high amount of system real estate.

In various embodiments, two or more dies are stacked on top of each other and disposed on and in electrical communication with a system substrate. The dies may include a substrate made of a semiconductor material, such as silicon, and transistors, resistors, insulators, conductors, and/or other components formed in or on the substrate to form digital and/or analog logic. The system substrate may be another substrate, a motherboard, or any other such device. The dies may include any circuit, memory, storage, or any other device; in some embodiments, the dies are memory components such as low-power double data rate 3 (“LPDDR3”) dynamic random-access memory (“DRAM”). The system substrate may similarly include any circuit, memory, storage, or any other device. A set of metal columns electrically connects each die with the system substrate. A first set of metal columns having a first height of, for example, 18 microns, connects a first die to the system substrate; solder bumps may be used to connect to connect the metal columns to the first die and/or system substrate. The first die may have a thickness of 15-20 microns; in some embodiments, the thickness of the first die is 18 microns. A second die is disposed at least partially on top of the first die such that at least a portion of the first die is disposed between the second die and the system substrate. A second set of metal columns having a second height of, for example, 90-120 microns, connects the second die to the system substrate; solder bumps may be used to connect to connect the metal columns to the second die and/or system substrate. An adhesive film may be used to connect the first and second die, and an underfill layer may be added between the first die and the system substrate. Stacking the dies in accordance with the embodiments disclosed herein may allow a 40-50% reduction in the area required on the system substrate for the dies, as compared to unstacked dies.

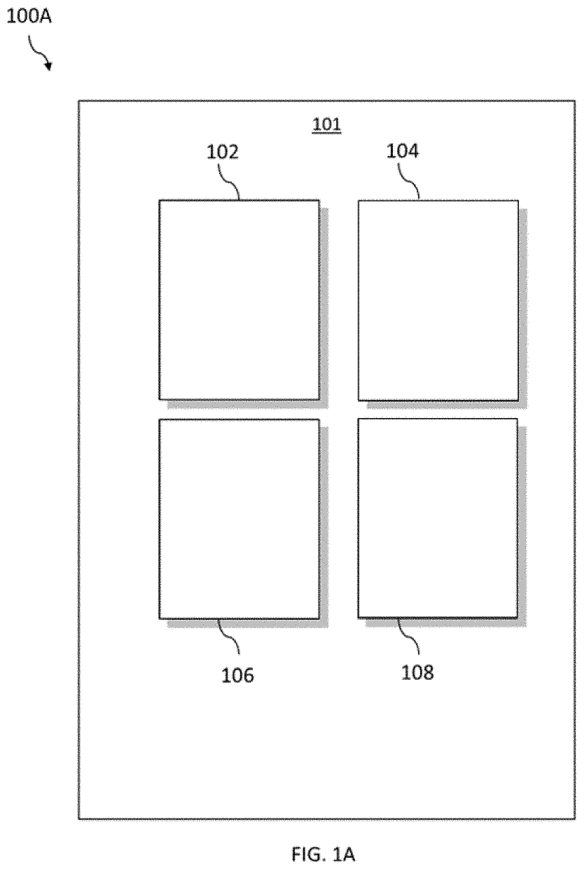

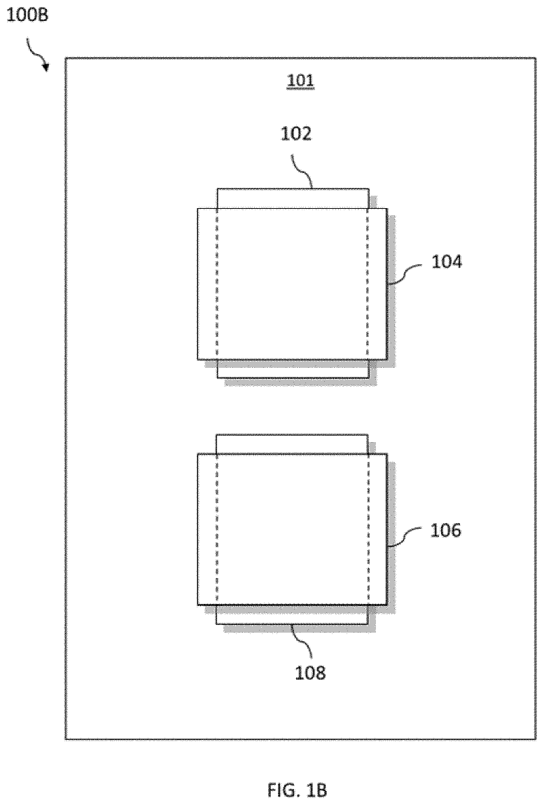

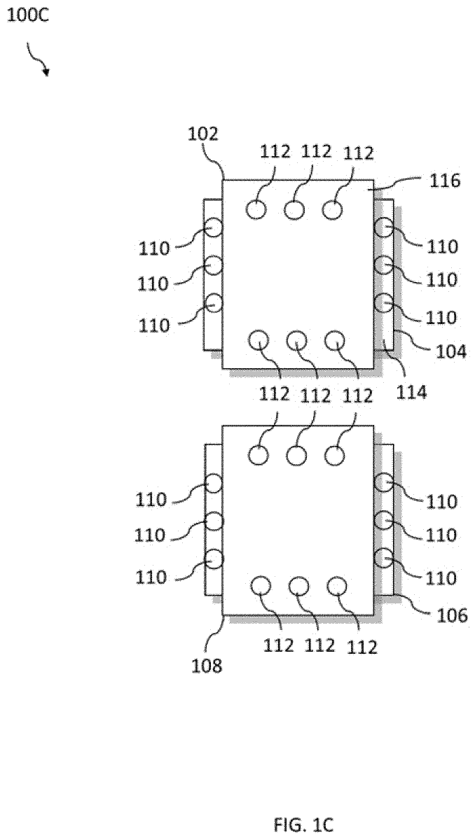

FIGS. 1A, 1B, and 1C illustrate electronic assemblies that include stacked dies in accordance with embodiments described herein. Although a particular number of stacked dies are described by way of example, one of skill in the art will understand that any number of stacked dies may be used for a given implementation. Embodiments are not limited in this context.

In FIG. 1A, a top view 100A of four dies 102, 104, 106, 108 in an unstacked configuration on a system substrate 101 is shown. As the term is used herein, a “top view” of a die refers to view of the die as if looking down on it as it is disposed on a system substrate; in the case of a flip-chip die, the top view presents a view of the back plane of the die. A “bottom view” of a die refers to a view of the die as if looking at it from the point of view of the system substrate; in the case of a flip-chip die, the bottom view presents a view of columns, bumps, upper metal layers, and/or packaging layers of the die. In FIG. 1B, a top view 100B is shown of a die 104 stacked on top of another die 102 with respect to the system substrate 101, and a die 106 stacked on top of another die 108 with respect to the system substrate 101. Throughout this disclosure, dies stacked below other dies with respect to a system substrate (i.e., dies disposed between the system substrate and other dies) may be referred to as lower-stack or first dies, and dies stacked on top of other dies with respect to a system substrate may be referred to as upper-stack or second dies. In FIG. 1C, a bottom view 100C that corresponds to the top view 100B of FIG. 1B is shown; the system substrate is not shown in this view 100C. In this view 100C, a plurality of metal columns 110 (which may be attached to and/or include solder bumps) may be disposed on the upper-stack dies 104, 106 (now appearing behind lower-stack dies 102, 108), and a plurality of metal columns 112 (which may be attached to and/or include, as explained in greater detail below, solder bumps) may be disposed on lower-stack dies 102, 108. At least a portion 114 of the upper-stack dies 104, 106 may extend beyond the perimeter of the lower-stack dies 102, 108 to permit placement of the metal columns 110. In this embodiment, a portion 116 of the lower-stack dies 102, 108 extends beyond a portion of the upper-stack dies 104, 106; in other embodiments, however, no portion of the lower-stack dies 102, 108 extends beyond the perimeter of the upper-stack dies 104, 106. In addition, in this embodiment, only one lower-stack die 102, 108 is disposed below upper-stack die 104, 106; in other embodiments, however, any number of lower-stack dies 102, 108 may be disposed below upper-stack dies 104, 106.

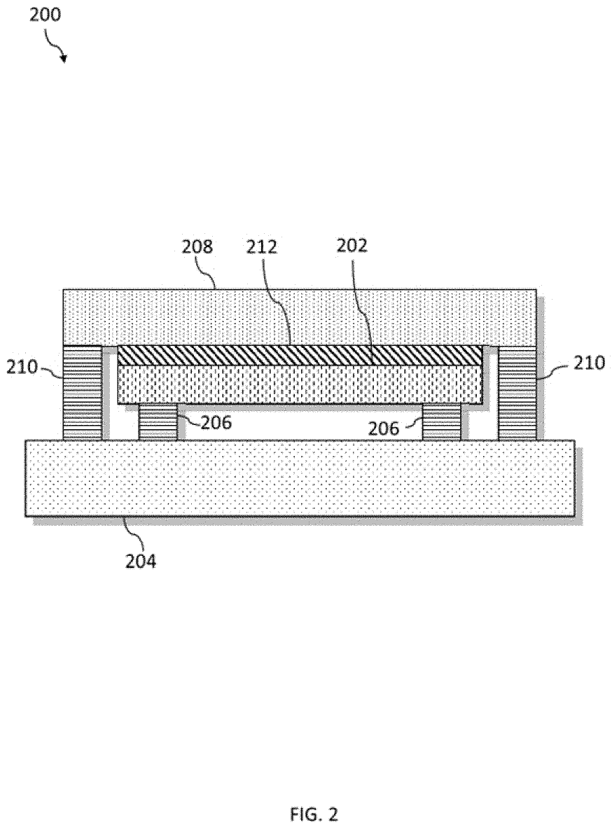

FIG. 2 illustrates a cross-sectional view of an electronic assembly 200 that includes stacked dies in accordance with embodiments disclosed herein. A first, lower-stack die 202 is electrically connected to a system substrate 204 via first metal columns 206, and a second, upper-stack die 208 is electrically connected to the system substrate 204 via second metal columns 210. In some embodiments, an adhesive film 212 is disposed between the lower-stack die 202 and the upper-stack die 208; the adhesive film 212 may adhere to both the lower-stack die 202 and the upper-stack die 208 to hold them in place with respect to each other.

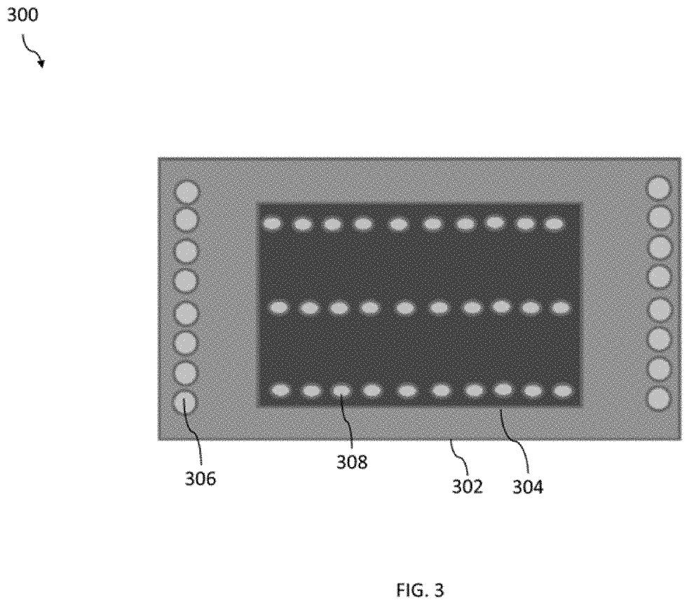

FIG. 3 illustrates a bottom view of an electronic assembly 300 that includes an upper-stack die 302 and a lower-stack die 304. In this exemplary embodiment, no portion of the lower-stack die 304 extends beyond a perimeter of the upper-stack die 302. A plurality of metal columns 306 are disposed on the surface of the upper-stack die 302, and a plurality of metal columns 308 are disposed on the surface of the lower-stack die 304. The metal columns 306, 308 may be attached to and/or include solder bumps.

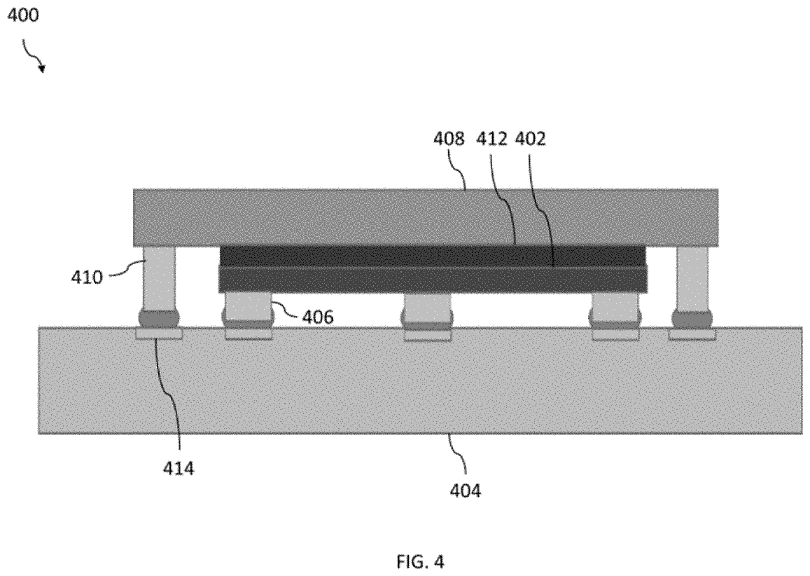

FIG. 4 illustrates a cross-sectional view of an electronic assembly 400 that includes stacked dies in accordance with embodiments disclosed herein. A first, lower-stack die 402 is electrically connected to a system substrate 404 via first metal columns 406, and a second-upper-stack die 408 is electrically connected to the system substrate 404 via second metal columns 410. In some embodiments, an adhesive film 412 is disposed between the lower-stack die 402 and the upper-stack die 408; the adhesive film 412 may adhere to both the lower-stack die 402 and the upper-stack die 408 to hold them in place with respect to each other. A solder bump 414 may be used to attach the metal columns 406, 410 to the system substrate 404.

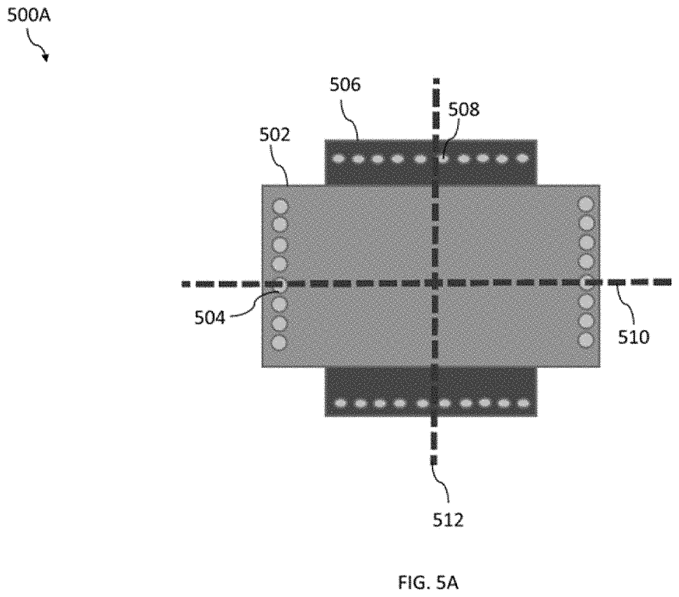

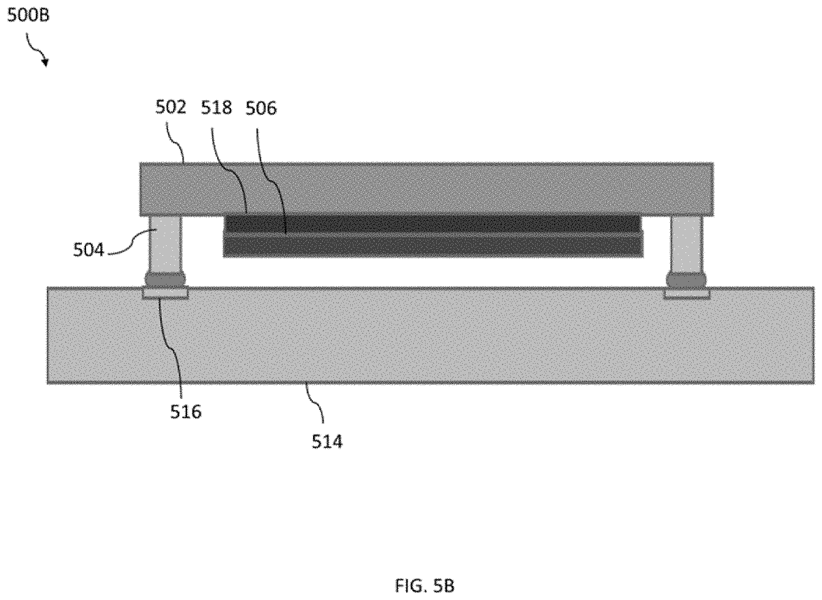

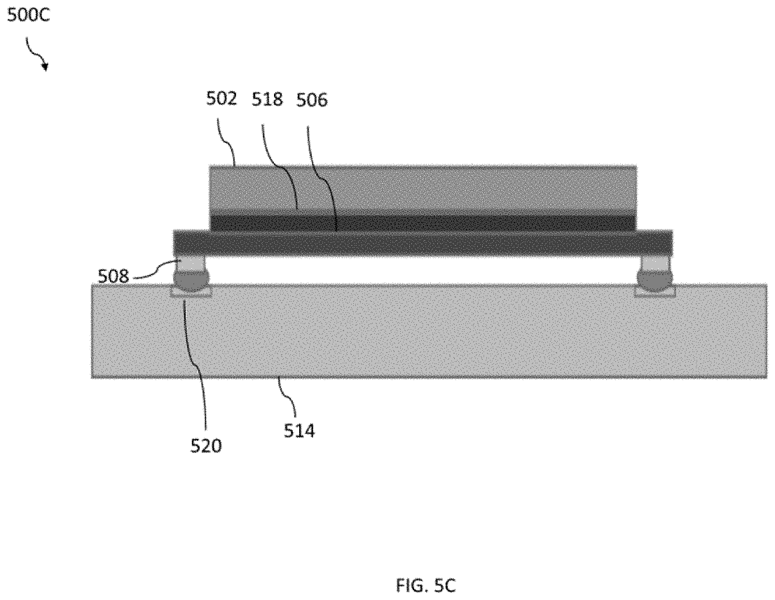

FIGS. 5A, 5B, and 5C illustrate a top view, a cross-sectional view, and another cross-sectional view, respectively, of an electronic assembly 500A, 500B, 500C that includes stacked dies in accordance with embodiments disclosed herein. FIG. 5A illustrates an upper-stack die 502 that includes metal columns 504 (which may be attached to and/or include, as explained in greater detail below, solder bumps) and a lower-stack die 506 that includes metal columns 508 (which may be attached to and/or include, as explained in greater detail below, solder bumps). FIG. 5B is a cross-sectional view of FIG. 5A along a first reference line 510, and FIG. 5C is a cross-sectional view of FIG. 5A along a second reference line 512.

In FIG. 5B, the cross-sectional view 500B includes the upper-stack die 502 electrically connected to a system substrate 514 via the metal column 504; in this embodiment, the metal column 504 is attached to the system substrate 514 using a solder bump 516. Note that the metal columns 508 associated with the lower-stack die 506 do not appear in this view 500B. In some embodiments, an adhesive film 518 is disposed between the upper-stack die 502 and the lower-stack die 506. In FIG. 5C, the cross-sectional view 500C includes the lower-stack die 506 electrically connected to the system substrate 514 via the metal column 508; in this embodiment, the metal column 504 is attached to the system substrate 514 using a solder bump 520. Note that the metal columns 504 associated with the upper-stack die 502 do not appear in this view 500C.

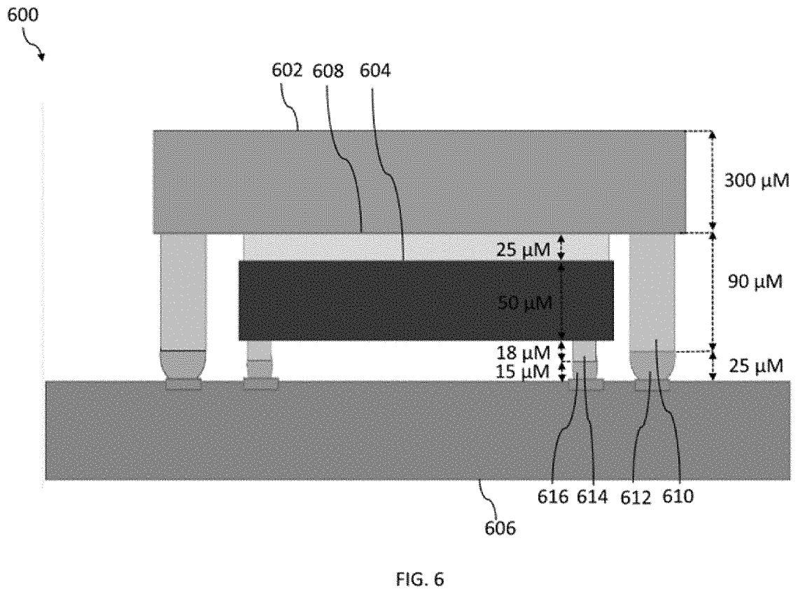

FIG. 6 illustrates a cross-sectional view of an electronic assembly 600 that includes an upper-stack die 602, a lower-stack die 604, and a system substrate 606. The electronic assembly 600 further includes an adhesive layer 608, metal columns 610 and solder bumps 612 associated with the upper-stack die 602, and metal columns 614 and solder bumps 616 associated with the lower-stack die 604. The embodiments described herein are not limited to any particular thickness for any die, layer, metal column, or solder bump. As shown in the figure, the thickness of the upper-stack die 602 may be 300 microns; the thickness of the lower-stack die 604 may be 50 microns; the thickness of the adhesive layer 608 may be 25 microns; the thickness of the metal columns 610 and solder bumps 612 associated with the upper-stack die 602 may be 90 microns and 25 microns, respectively; and the thickness of the metal columns 614 and solder bumps 616 associated with the lower-stack die 604 may be 18 microns and 15 microns, respectively.

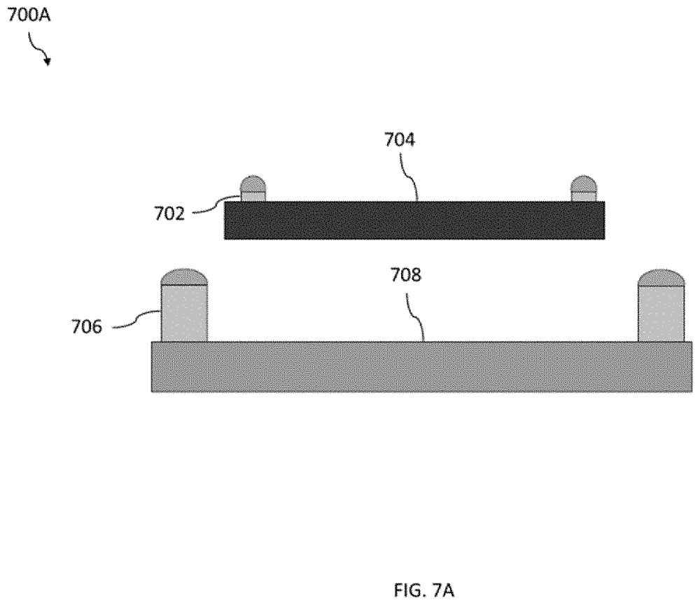

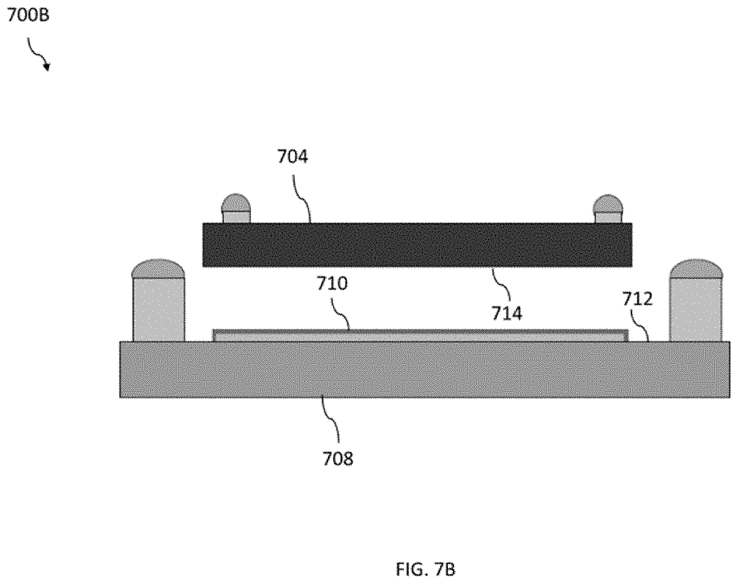

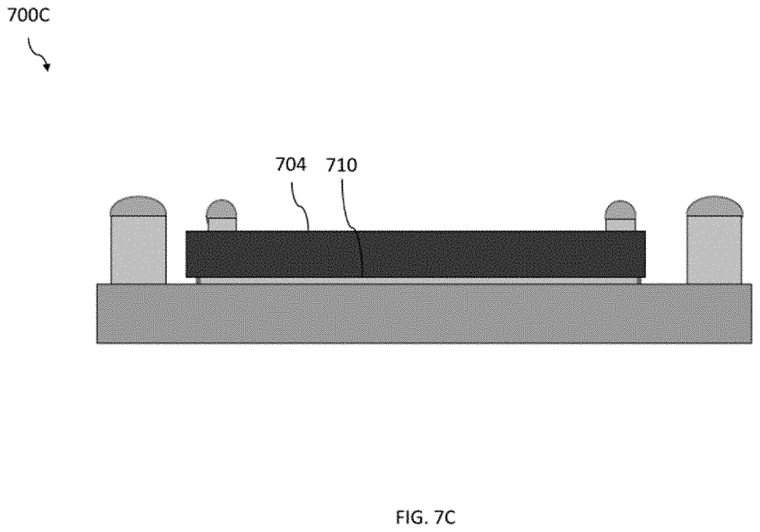

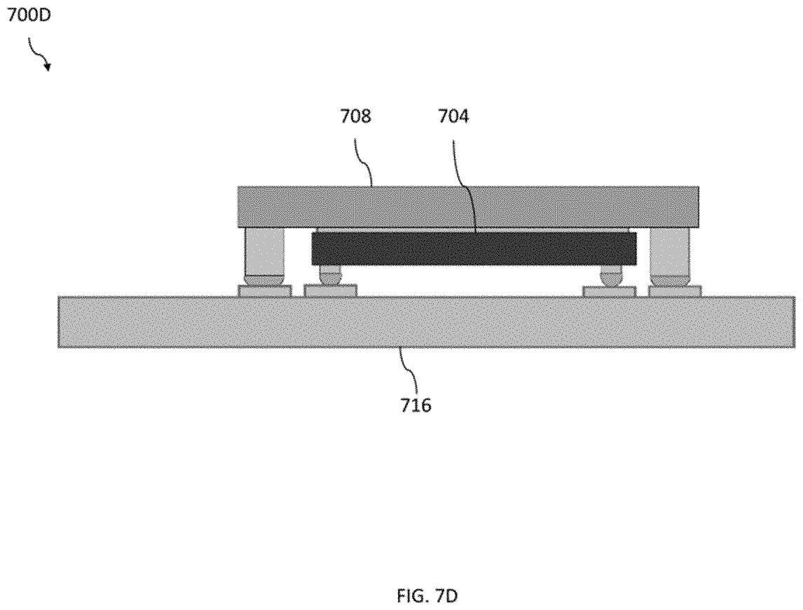

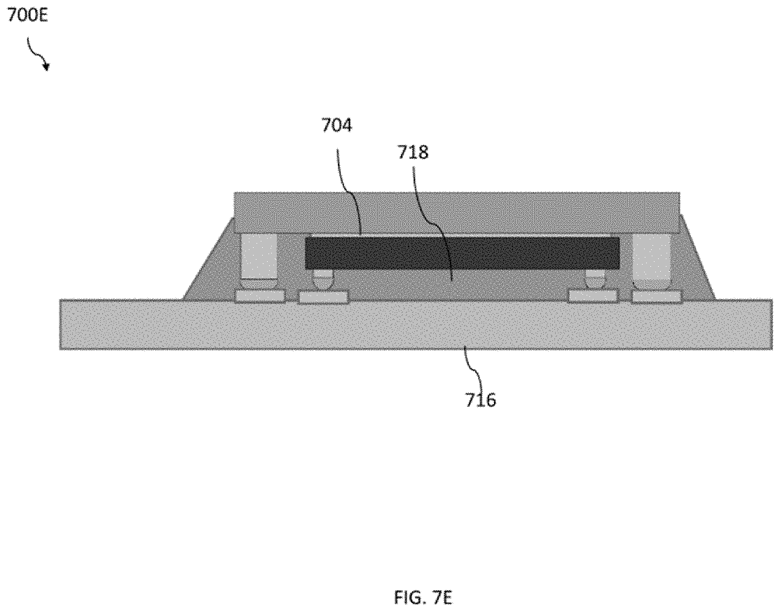

FIGS. 7A, 7B, 7C, 7D, and 7E illustrate a method for forming an electronic assembly in accordance with embodiments disclosed herein. FIG. 7A is a view 700A in which a first set of metal columns 702 is formed on a first die 704 and a second set of metal columns 706 is formed on a second die 708. The metal columns 702, 706 may be formed using any method or technique known in the art; in some embodiments, the metal columns 702, 706 are formed following formation of a redistribution layer that converts a wire-bond die to a flip-chip die. FIG. 7B is a view 700B in which an adhesive film 710 is deposited on a surface 712 of the second die 708. Alternatively or in addition, the adhesive film 710 may be deposited on a surface 714 of the first die 704. The adhesive film 710 may be a die-attached film (“DAF”). FIG. 7C is a view 700C in which the surface 714 of the first die 704 is attached to the adhesive film 710. FIG. 7D is a view 700D in which the dies 704, 708 are attached to a system substrate 716 via metal columns 702, 706 using, for example, a thermo-compression bonding process.

FIG. 7D is a view 700E in which an underfill layer is added between the first die 704 and the system substrate 716.

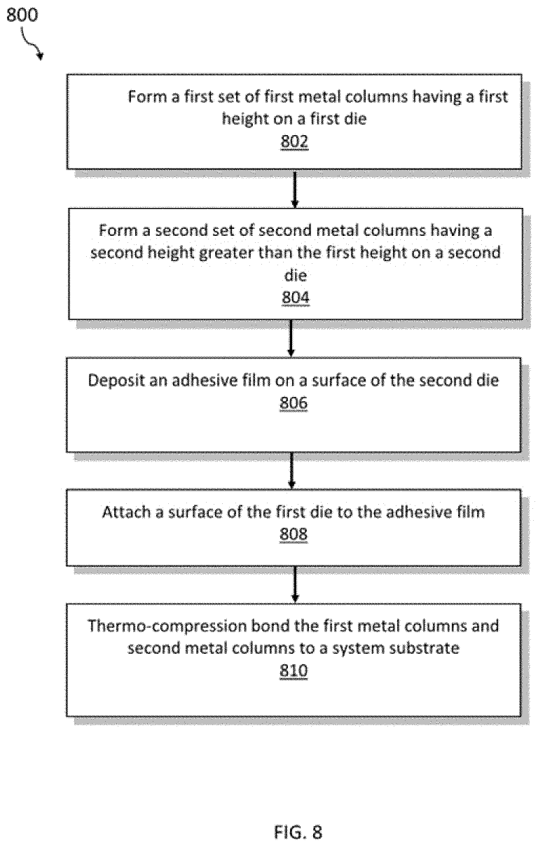

FIG. 8 illustrates a method 800 a method for forming an electronic assembly. A first set of first metal columns having a first height is formed (802) on a first die, and a second set of second metal columns having a second height greater than the first height is formed (804) on a second die. An adhesive film is deposited (806) on a surface of the second die. A surface of the first die is attached (808) to the adhesive film. The first metal columns and second metal columns are thermo-compression bonded (810) to a system substrate.

In various embodiments, an electronic assembly comprising a system substrate may communicate electronically with a first (i.e., lower-stack) die and a second (i.e., upper-stack die). The system substrate may transmit a first signal through a first set of first metal columns having a first height on a first die and transmit a second signal through a second set of second metal columns having a second height greater than the first height on a second die. At least a portion of the first die may be disposed between the second die and the system substrate, as described above.

Example 1 is an electronic assembly comprising a system substrate; a first die disposed on and in electrical communication with the system substrate using a first set of first metal columns having a first height; a second die disposed on and in electrical communication with the system substrate using a second set of second metal columns having a second height greater than the first height such that at least a portion of the first die is disposed between the second die and the system substrate.

Example 2 includes the subject matter of example 1, further comprising an adhesive film disposed between the first die and the second die.

Example 3 includes the subject matter of example 1, where the first die comprises a flip-chip die and the second die comprising a flip-chip die.

Example 4 includes the subject matter of example 1, the first die comprising a converted wire-bond die and the second die comprising a converted wire-bond die.

Example 5 includes the subject matter of example 1, further comprising a third die disposed on and in electrical communication with the system substrate using a third set of third metal columns having a third height such that at least a portion of the third die is disposed between the second die and the system substrate.

Example 6 includes the subject matter of example 1, where a portion of the first die extend beyond a perimeter of the second die.

Example 7 includes the subject matter of example 1, the first die comprising a dynamic random-access memory.

Example 8 includes the subject matter of example 1, further comprising an underfill layer disposed between the first die and the system substrate.

Example 9 includes the subject matter of example 1, where the first metal columns comprise copper.

Example 10 includes the subject matter of example 1, where the first metal columns comprise a solder bump.

Example 11 includes the subject matter of example 1, where the first height comprises 15-20 microns.

Example 12 includes the subject matter of example 11, where the first height comprises 18 microns.

Example 13 includes the subject matter of example 1, where the second height comprises 90-120 microns.

Example 14 includes the subject matter of example 13, where the second height comprises 90 microns.

Example 15 includes the subject matter of example 1, where a thickness of the first die comprises 50 microns.

Example 16 includes the subject matter of example 1, where a thickness of the second die comprises 300 microns.

Example 17 is a method for forming an electronic assembly, the method comprising forming a first set of first metal columns having a first height on a first die; forming a second set of second metal columns having a second height greater than the first height on a second die; depositing an adhesive film on a surface of the second die; attaching a surface of the first die to the adhesive film; thermo-compression bonding the first metal columns and second metal columns to a system substrate.

Example 18 includes the subject matter of example 17, further comprising depositing an underfill layer between the second die and the system substrate.

Example 19 includes the subject matter of example 17, further comprising depositing solder bumps on the first columns and second columns

Example 20 includes the subject matter of example 17, further comprising converting the first die from a wire-bond die to a flip-chip die.

Example 21 includes the subject matter of example 17, further comprising forming the first die to have a thickness comprising 50 microns.

Example 22 includes the subject matter of example 17, further comprising forming the second die to have a thickness comprising 300 microns.

Example 23 includes the subject matter of example 17, where the first height comprises 15-20 microns.

Example 24 includes the subject matter of example 23, where the first height comprises 18 microns.

Example 25 includes the subject matter of example 17, where the second height comprises 90-120 microns.

Example 26 includes the subject matter of example 25, where the second height comprises 90 microns.

Example 27 is a method for electronically communicating with circuits disposed on a plurality of dies, the method comprising transmitting a first signal from a system substrate through a first set of first metal columns electrically connected to the system substrate and having a first height to a first die electrically connected to the first set of first metal columns; transmitting a second signal from a system substrate through a second set of second metal columns electrically connected to the system substrate and having a second height greater than the first height to a second die electrically connected to the second set of second metal columns, at least a portion of the first die being disposed between the second die and the system substrate.

Example 28 includes the subject matter of example 27, further comprising depositing an underfill layer between the second die and the system substrate.

Example 29 includes the subject matter of example 27, further comprising depositing solder bumps on the first columns and second columns.

Example 30 includes the subject matter of example 27, further comprising converting the first die from a wire-bond die to a flip-chip die.

Example 31 includes the subject matter of example 27, further comprising forming the first die to have a thickness comprising 50 microns.

Example 32 includes the subject matter of example 27, further comprising forming the second die to have a thickness comprising 300 microns.

Example 33 includes the subject matter of example 27, where the first die comprises a dynamic random-access memory.

Example 34 includes the subject matter of example 27, where the first metal columns comprise copper.

Example 35 includes the subject matter of example 27, where the first metal columns comprise a solder bump.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Further, some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “including” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications, and variations that fall within the spirit and scope of the appended claims.

What is claimed is:

1. An electronic assembly comprising:
a system substrate;
a first die disposed on and in electrical communication with the system substrate using a first set of first metal columns having a first height;
a second die disposed on and in electrical communication with the system substrate using a second set of second metal columns having a second height greater than the first height such that at least a portion of the first die is disposed between the second die and the system substrate.

2. The electronic assembly of claim 1, further comprising an adhesive film disposed between the first die and the second die.

3. The electronic assembly of claim 1, the first die comprising a flip-chip die and the second die comprising a flip-chip die.

4. The electronic assembly of claim 1, the first die comprising a converted wire-bond die and the second die comprising a converted wire-bond die.

5. The electronic assembly of claim 1, further comprising a third die disposed on and in electrical communication with the system substrate using a third set of third metal columns having a third height such that at least a portion of the third die is disposed between the second die and the system substrate.

6.-25. (canceled)

25. The electronic assembly of claim 1, further comprising a third die disposed on and in electrical communication with the system substrate using a third set of third metal columns having a third height and a fourth die disposed on and in electrical communication with the system substrate using a fourth set of fourth metal columns having a fourth height greater than the third height such that at least a portion of the third die is disposed between the fourth die and the system substrate.

26. The electronic assembly of claim 1, a portion of the first die extending beyond a perimeter of the second die.

27. The electronic assembly of claim 1, wherein the first die and the second die comprise identical devices but each has a thickness that differs from the other.

28. The electronic assembly of claim 1, wherein the first die and the second die comprise identical memory devices but each has a thickness that differs from the other.

29. The electronic assembly of claim 1, wherein the first die and the second die comprise identical dynamic random-access memory (DRAM) devices but each has a thickness that differs from the other.

30. The electronic assembly of claim 1, wherein the first die and the second die comprise identical non-volatile memory devices but each has a thickness that differs from the other.

31. The electronic assembly of claim 1, wherein the first die comprises a thickness of 50 microns and wherein the second die comprises a thickness of 300 microns.

32. The electronic assembly of claim 1, wherein the first die and the second die comprise identical devices, wherein the first die comprises a thickness of 50 microns, and wherein the second die comprises a thickness of 300 microns.

33. The electronic assembly of claim 1, wherein the first die and the second die comprise identical DRAM devices, wherein the first die comprises a thickness of 50 microns, and wherein the second die comprises a thickness of 300 microns.

34. The electronic assembly of claim 1, wherein the first die and the second die comprise identical non-volatile memory devices, wherein the first die comprises a thickness of 50 microns, and wherein the second die comprises a thickness of 300 microns.

35. A method for forming an electronic assembly, the method comprising:
a. forming a first set of first metal columns having a first height on a first die;
b. forming a second set of second metal columns having a second height greater than the first height on a second die;
c. depositing an adhesive film on a surface of the second die;
d. attaching a surface of the first die to the adhesive film;
e. thermo-compression bonding the first metal columns and second metal columns to a system substrate.

36. The method of claim 35, further comprising depositing an underfill layer between the second die and the system substrate.

37. The method of claim 35, further comprising depositing solder bumps on the first columns and second columns.

38. The method of claim 35, further comprising converting the first die from a wire-bond die to a flip-chip die.

39. The method of claim 35, further comprising forming the first die to have a thickness comprising 50 microns.

40. The method of claim 35, further comprising forming the second die to have a thickness comprising 300 microns.

41. The method of claim 35, further comprising back-side grinding the first die.

42. A method for electronically communicating with circuits disposed on a plurality of dies, the method comprising:
transmitting a first signal from a system substrate through a first set of first metal columns electrically connected to the system substrate and having a first height to a first die electrically connected to the first set of first metal columns;
transmitting a second signal from a system substrate through a second set of second metal columns electrically connected to the system substrate and having a second height greater than the first height to a second die electrically connected to the second set of second metal columns, at least a portion of the first die being disposed between the second die and the system substrate.

43. The method of claim 42, wherein, prior to back-side grinding the first die, the first die and the second die comprise a same thickness.

44. The method of claim 42, wherein, after back-side grinding the first die, the first die comprises a thickness of 50 microns.
